(19) United States
(12) Patent Application Publication
(10) Pub. No.: US 2005/0052095 A1
(43) Pub. Date: Mar. 10, 2005

(54) Ultrasonic actuator driving apparatus and ultrasonic actuator driving method

(75) Inventors: Yasuaki Kasai, Tokyo (JP); Masahiro Nishio, Tokyo (JP)

Correspondence Address: SCULLY SCOTT MURPHY & PRESSER, PC, 400 GARDEN CITY PLAZA, GARDEN CITY, NY, 11530, US

(73) Assignee: Olympus Corporation, Tokyo (JP)

(21) Appl. No.: 10/936,028

(22) Filed: Sep. 8, 2004

(30) Foreign Application Priority Data
Sep. 9, 2003 (JP) 2003-317382
Jun. 24, 2004 (JP) 2004-186952

(51) Int. Cl. H01L 41/09

(52) U.S. Cl. 310/317

(57) ABSTRACT

An ultrasonic actuator driving apparatus which drives an ultrasonic transducer formed by alternately laminating a piezoelectric plate and an internal electrode, by applying a frequency signal to the ultrasonic transducer, includes an oscillating unit which generates the frequency signal for driving the ultrasonic transducer, a driving unit which amplifies the frequency signal and applies the signal to the ultrasonic transducer based on an output from the oscillating unit, a vibration information detecting unit which detects vibration information of the ultrasonic transducer, and, a control unit which detects a frequency near a resonant one of the ultrasonic transducer based on the vibration information, sets the detected frequency as a driving frequency of the ultrasonic transducer, and controls the oscillating unit so as to generate the frequency signal based on the driving frequency.

This application claims benefit of Japanese Application Nos. 2003-317382 filed on Sep. 9, 2003 and 2004-186952 filed in Japan on Jun. 24, 2004, the contents of which are incorporated by this reference.

### BACKGROUND OF THE INVENTION

1. Field of the Invention

The present invention relates to an ultrasonic actuator driving apparatus and an ultrasonic actuator driving method. More particularly, the present invention relates to an ultrasonic actuator driving apparatus and an ultrasonic actuator driving method, by which driving force is generated by applying a driving signal with a frequency voltage to e.g., a laminating ultrasonic transducer of an ultrasonic actuator.

2. Description of the Related Art

Recently, attention is paid to an ultrasonic actuator as a new motor, in place of an electromagnetic motor. The ultrasonic actuator has the following advantages, as compared with the conventional electromagnetic motor.
(1) High thrust and low speed without any gears
(2) Retentive
(3) Long stroke and high resolution
(4) Silent
(5) No magnetic noises and no influence from noises

The ultrasonic actuator with the above-mentioned advantages is usually controlled by an actuator driving apparatus. The actuator driving apparatus applies a driving signal with a frequency voltage to an ultrasonic transducer of the ultrasonic actuator and then generates ultrasonic elliptical vibrations in the ultrasonic transducers. Consequently, the actuator driving apparatus controls the ultrasonic actuator or ultrasonic transducer so as to obtain the driving force via a driven member in contact with the ultrasonic transducer or ultrasonic transducer.

As a conventional technology of the above-mentioned ultrasonic actuator driving apparatus, Japanese Unexamined Patent Application Publication No. 1-160379 discloses an ultrasonic motor driving apparatus.

The above-suggested ultrasonic motor driving apparatus comprises means for detecting a current amplitude of current of a mechanical arm, which flows in an electric equivalent circuit (serial circuit of L, Cl, and R in FIG. 2) of the ultrasonic actuator upon driving the ultrasonic actuator (ultrasonic motor). In the ultrasonic motor driving apparatus, the ultrasonic actuator is driven by a driving signal with a frequency voltage of frequency higher than a resonant frequency of the ultrasonic actuator, except for the frequency voltage near the resonant frequency, the frequency and amplitude of the driving signal change, and the current of the mechanical arm is controlled to have predetermined level.

### SUMMARY OF THE INVENTION

Briefly, according to the present invention, an ultrasonic actuator driving apparatus drives an ultrasonic transducer formed by alternately laminating a piezoelectric plate and an internal electrode, by applying a frequency signal to the ultrasonic transducer. The ultrasonic actuator driving apparatus comprises: an oscillating unit which generates the frequency signal for driving the ultrasonic transducer; a driving unit which amplifies the frequency signal and applies the signal to the ultrasonic transducer based on an output from the oscillating unit; a vibration information detecting unit which detects vibration information of the ultrasonic transducer; and a control unit which detects a frequency near a resonant one of the ultrasonic transducer based on the vibration information, sets the detected frequency as a driving frequency of the ultrasonic transducer, and controls the oscillating unit so as to generate the frequency signal based on the driving frequency.

Further, according to the present invention, an ultrasonic actuator driving method which drives an ultrasonic transducer formed by alternately laminating a piezoelectric plate and an internal electrode, by applying a frequency signal to the ultrasonic transducer, comprises the steps of: detecting a frequency near a resonant one of the ultrasonic transducer based on vibration information of the ultrasonic transducer; setting the detected frequency as a driving frequency of the ultrasonic transducer; and driving the ultrasonic transducer by applying the frequency signal to the ultrasonic transducer based on the driving frequency.

### BRIEF DESCRIPTION OF THE DRAWINGS

FIG. 1 is a block diagram showing the entire structure of an ultrasonic actuator driving apparatus according to a first embodiment of the present invention;

FIG. 2A is one graph showing characteristics of the frequency with respect to the phase difference between the voltage and the current in the initial detection, for explaining a driving method of the ultrasonic actuator driving apparatus according to the first embodiment and a method for detecting the frequency voltage near the resonant frequencies based on the detecting result from a vibration information detecting unit shown in FIG. 1;

FIG. 2B is another graph showing characteristics of the frequency with respect to the phase difference between the voltage and the current in the detecting process, for explaining the driving method of the ultrasonic actuator driving apparatus according to the first embodiment and a method for detecting the frequency voltage near the resonant frequencies based on the detecting result from the vibration information detecting unit shown in FIG. 1;

FIG. 3 is a flowchart showing a control example of a processing routine for detecting a resonant frequency in a control unit shown in FIG. 1;

FIG. 4A is a graph showing characteristics of the frequency with respect to the velocity and showing characteristics of the ultrasonic actuator driven according to the ultrasonic actuator driving method according to the first embodiment;

FIG. 4B is a graph showing characteristics of the frequency with respect to the phase difference between the voltage and the current and showing characteristics of the ultrasonic actuator driven according to the ultrasonic actuator driving method according to the first embodiment;

FIG. 5 is a diagram showing a first structure-example of an ultrasonic actuator used for the ultrasonic actuator driving apparatus according to the first embodiment;

FIG. 6 is a diagram showing a second structure-example of an ultrasonic actuator used for the ultrasonic actuator driving apparatus according to the first embodiment;

FIG. 7 is an exploded perspective view showing a piezoelectric laminated member which is laminated in the Y-axial direction;

FIG. 8 is an exploded perspective view showing a piezoelectric laminated member which is laminated in the Z-axial direction;

FIG. 9 is an exploded perspective view showing a piezoelectric laminated member which is laminated in the X-axial direction;

FIG. 10A is a front view showing a third structure-example of the ultrasonic actuator used for the ultrasonic actuator driving apparatus according to the first embodiment;

FIG. 10B is a side view showing the ultrasonic actuator shown in FIG. 10A;

FIG. 11 is a side view showing a fourth structure-example of the ultrasonic actuator used for the ultrasonic actuator driving apparatus according to the first embodiment;

FIG. 12 is a front view showing a fifth structure-example of the ultrasonic actuator used for the ultrasonic actuator driving apparatus according to the first embodiment;

FIG. 13 is a front view showing a sixth structure-example of the ultrasonic actuator used for the ultrasonic actuator driving apparatus according to the first embodiment;

FIG. 14 is a block diagram showing the entire structure of an ultrasonic actuator driving apparatus according to a second embodiment of the present invention;

FIG. 15 is a block diagram showing the entire structure of an ultrasonic actuator driving apparatus according to a third embodiment of the present invention;

FIG. 16 is a block diagram showing the entire structure of an ultrasonic actuator driving apparatus according to a fourth embodiment of the present invention;

FIG. 17 is a block diagram showing the entire structure of an ultrasonic actuator driving apparatus according to a fifth embodiment of the present invention;

FIG. 18A is an explanatory diagram for characteristics of the frequency with respect to the displacement amount in the first oscillating-mode in the longitudinal direction of the ultrasonic transducer according to the present invention;

FIG. 18B is an explanatory diagram for characteristics of the frequency with respect to the displacement amount in the second oscillating-mode in the bending direction of the ultrasonic transducer according to the present invention;

FIG. 19 is an explanatory diagram for characteristics of the frequency with respect to the velocity of the ultrasonic transducer according to the present invention;

FIG. 20A is a waveform diagram showing a frequency signal for driving the ultrasonic actuator in the forward direction, explaining the frequency signal applied to the ultrasonic transducer as a rectangular wave (single pole) according to the present invention;

FIG. 20B is a waveform diagram showing a frequency signal for driving the ultrasonic actuator in the backward direction, explaining the frequency signal applied to the ultrasonic transducer as the rectangular wave (single pole) according to the present invention;

FIG. 21A is a waveform diagram showing a frequency signal for driving the ultrasonic actuator in the forward direction, explaining the frequency signal applied to the ultrasonic transducer as a sine wave (single pole) according to the present invention;

FIG. 21B is a waveform diagram showing a frequency signal for driving the ultrasonic actuator in the backward direction, explaining the frequency signal applied to the ultrasonic transducer as the sine wave (single pole) according to the present invention;

FIG. 22A is a waveform diagram showing a frequency signal for driving the ultrasonic actuator in the forward direction, explaining the frequency signal applied to the ultrasonic transducer as a rectangular wave (bi-pole) according to the present invention;

FIG. 22B is a waveform diagram showing a frequency signal for driving the ultrasonic actuator in the backward direction, explaining the frequency signal applied to the ultrasonic transducer as the rectangular wave (bi-pole) according to the present invention;

FIG. 23A is a waveform diagram showing a frequency signal for driving the ultrasonic actuator in the forward direction, explaining the frequency signal applied to the ultrasonic transducer as a sine wave (bi-pole) according to the present invention; and

FIG. 23B is a waveform diagram showing a frequency signal for driving the ultrasonic actuator in the backward direction, explaining the frequency signal applied to the ultrasonic transducer as the sine wave (bi-pole) according to the present invention.

### DETAILED DESCRIPTION OF THE PREFERRED EMBODIMENTS

Hereinbelow, a description is given of embodiments of the present invention with reference to the drawings.

### First embodiment

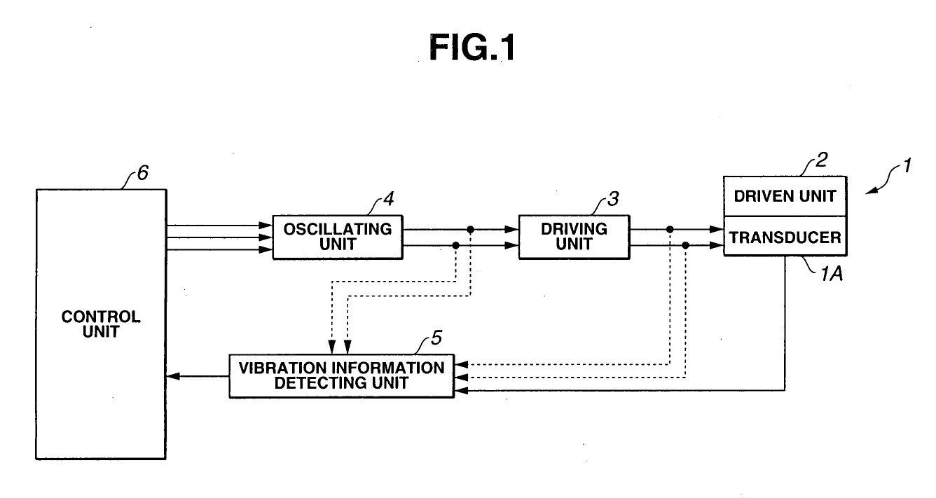

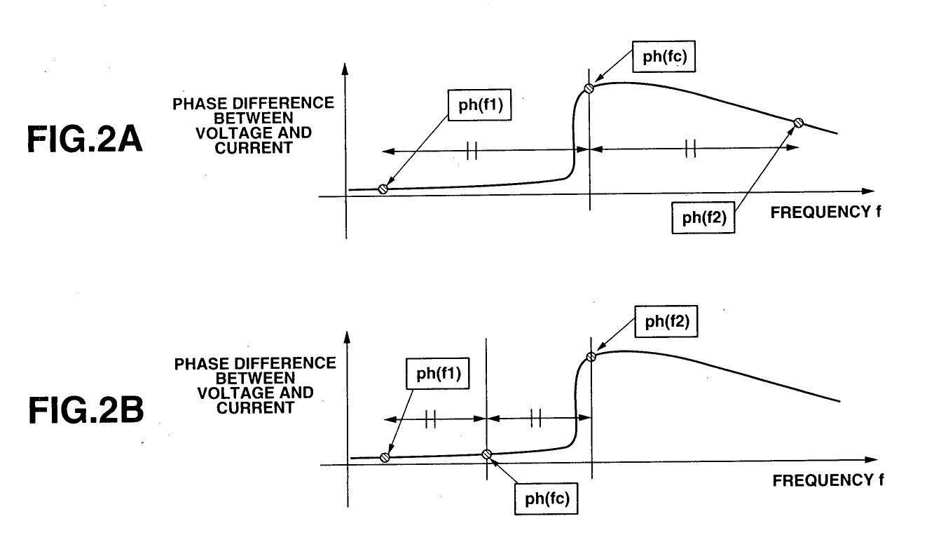

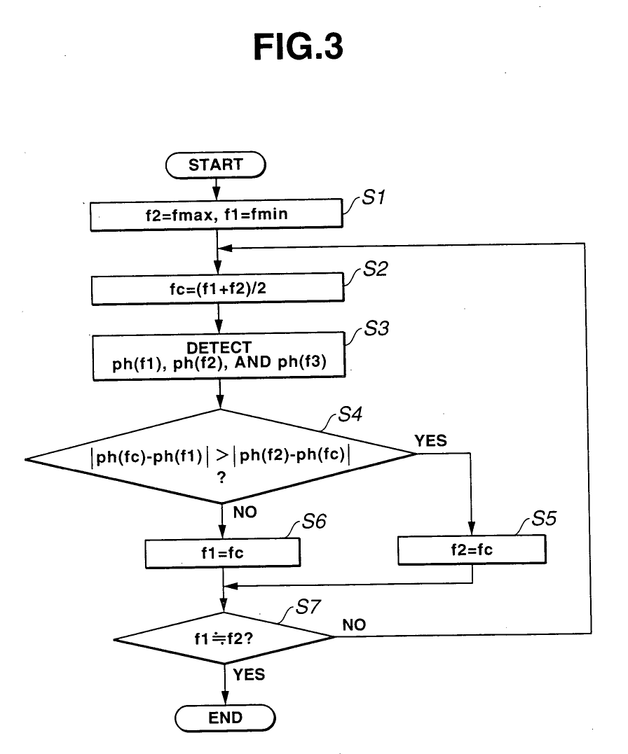

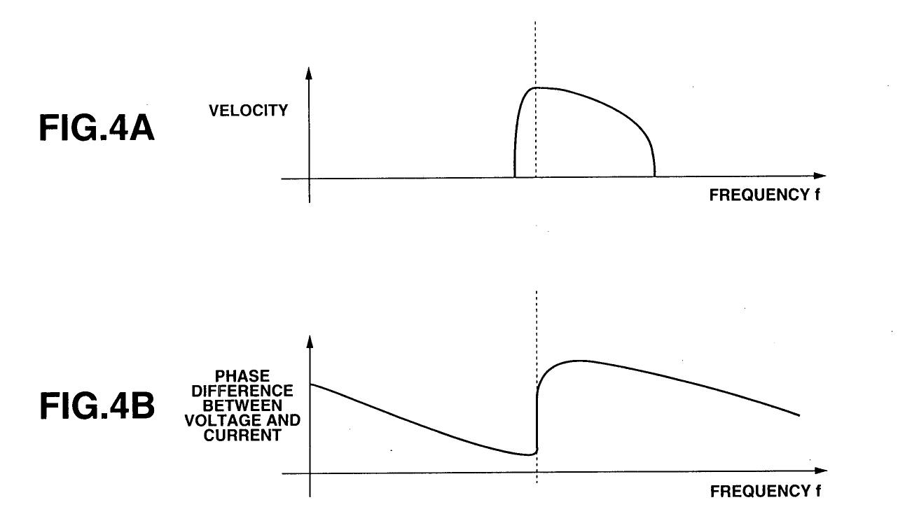

FIGS. 1 to 4B show an ultrasonic actuator driving apparatus according to the first embodiment of the present invention, FIG. 1 is a block diagram showing the entire structure of an ultrasonic actuator driving apparatus according to the first embodiment, FIGS. 2A, 2B, and 3 are diagrams for explaining a driving method of the ultrasonic actuator driving apparatus according to the first embodiment, FIGS. 2A and 2B are graphs for explaining a method for detecting the frequency voltage near the resonant frequencies based on the detecting result from a vibration information detecting unit shown in FIG. 1, FIG. 2A is a graph showing characteristics of the frequency with respect to the phase difference between the voltage and the current in the initial detection, FIG. 2B is a graph showing characteristics of the frequency with respect to the phase difference between the voltage and the current in the detecting process, FIG. 3 is a flowchart showing a control example of a resonant frequency detecting processing routine in a control unit shown in FIG. 1, FIGS. 4A and 4B are characteristic diagrams showing characteristics of the ultrasonic actuator driven by the ultrasonic actuator driving method according to the first embodiment, FIG. 4A is a graph showing characteristics of the frequency with respect to the velocity, and FIG. 4B is a graph showing characteristics of the frequency with respect to the phase difference between the voltage and the current.

Referring to FIG. 1, the ultrasonic actuator driving apparatus according to the first embodiment comprises: an ultrasonic actuator 1 which drives a laminating ultrasonic transducer (hereinafter, referred to as an ultrasonic transducer) 1A by using friction force generated between the ultrasonic transducer 1A and a driven unit 2 in contact therewith; a driving unit 3 which applies a driving signal of a frequency signal to the ultrasonic actuator 1; an oscillating unit 4 which generates an original signal of the frequency signal supplied to the driving unit 3 and determines the frequency of the frequency signal; a vibration information detecting unit 5 which detects a parameter indicating the oscillating state of the ultrasonic transducer 1A in the ultrasonic actuator 1; and a control unit 6 which controls an oscillating frequency of the oscillating unit 4 based on the detecting result of the vibration information detecting unit 5.

The driving unit 3 amplifies the frequency signal supplied from the oscillating unit 4, and outputs the amplified frequency signal to the ultrasonic transducer 1A of the ultrasonic actuator 1 as a driving signal, thereby driving the ultrasonic actuator 1.

The oscillating unit 4 is connected to the driving unit 3. Further, the oscillating unit 4 generates the original signal of the frequency signal which is phase-displaced at an angle of 90° under the control of the control unit 6, which will be described later, and outputs the generated signal to the driving unit 3.

The vibration information detecting unit 5 is electrically connected to the ultrasonic transducer 1A, detects a level of the parameter indicating the oscillating state of the ultrasonic transducer 1A and outputs the detecting result to the control unit 6.

The control unit 6 controls the oscillating frequency of the oscillating unit 4 so that the frequency signal applied to the ultrasonic transducer 1A becomes the resonant frequency of the ultrasonic transducer 1A. That is, the control unit 6 performs the detecting processing based on the level of the parameter indicating the oscillating state detected by the vibration information detecting unit 5 so as to detect the frequency voltage near the resonant frequency of the ultrasonic transducer 1A changing in oscillating state due to the external environment. Further, the control unit 6 controls the oscillating unit 4 so as to have the frequency signal near the detected resonant frequency.

Next, a description is given of the driving method of the ultrasonic actuator driving apparatus according to the first embodiment with reference to FIGS. 2A, 2B, and 3.

Referring to FIG. 2A, the ultrasonic actuator 1 has a characteristic that the phase difference between the voltage and the current sharply changes near the resonant frequency. According to the first embodiment, the control unit 6 performs the processing for detecting the resonant frequency by using the characteristic. That is, the vibration information detecting unit 5 detects the phase difference between the voltage and the current of the ultrasonic transducer 1A as the parameter indicating the oscillating state of the ultrasonic transducer 1A, and outputs the detected signal to the control unit 6.

Now, the driving method of the ultrasonic actuator driving apparatus is executed according to the first embodiment. The control unit 6 starts the processing routine for detecting the resonant frequency, including steps S1 to S7 shown in FIG. 3.

In step S1, the control unit 6 substitutes, into a frequency f2, a maximum value fmax within a frequency detecting area (having the maximum value fmax and a minimum value fmin) including the resonant frequency detected based on the characteristic of the phase difference between the voltage and the current shown in FIG. 2A, and further substitutes the minimum value fmin into a frequency f1.

In step S2, the control unit 6 calculates an intermediate value (f1+f2)/2 between the frequency f1 and the frequency f2, and substitutes the calculating result into a frequency fc.

Further, in step S3, the control unit 6 detects the phase difference between the voltage and the current (hereinafter, referred to as the phase difference) corresponding to the frequencies f1, f2, and fc, and substitutes the phase differences detected by the frequencies f1, f2, and fc, into ph(f1), ph(f2), and ph(fc), respectively.

Then, in determining processing in step S4, the control unit 6 compares the absolute |ph(fc)−ph(f1)| with the absolute |ph(f2)−ph(fc)|. When the absolute |ph(f2)−ph(fc)| is lower than the absolute |ph(fc)−ph(f1)|, in step S5, the control unit 6 replaces the frequency f2 with value of the frequency fc, and shifts to the processing in step S7. When the absolute |ph(fc)−ph(f1)| is lower than the absolute |ph(f2)−ph(fc)|, in step S6, the control unit 6 replaces the frequency f1 with the value of the frequency fc and shifts to the processing in step S7.

FIG. 2B shows a state in which |ph(f2)−ph(fc)| is lower. Therefore, as the result of the processing in step S5 which is executed by the control unit 6, the frequency f2 is replaced with the value of the frequency fc.

Then, in determining processing in step S7, the control unit 6 determines whether or not the frequency f1 is approximately equal to the frequency f2. In this case, the control unit 6 does not determine that a relation of f1≈f2, is not satisfied that is, when the control unit 6 determines that the frequency f1 is not equal to the frequency f2, the control unit 6 returns to the processing in step S2 and then continues the processing in step S2 again.

On the other hand, in the determining processing in step S7, when the control unit 6 determines that the relation of f1≈f2 is satisfied and the frequency f1 is approximately equal to the frequency f2, the control unit 6 recognizes that the relation of f1≈f2 is satisfied and sets the frequency value in this case as a value near the best resonant frequency for driving of the ultrasonic transducer 1A, and ends the processing routine for detecting the resonant frequency.

Therefore, the control unit 6 iteratively executes the processing in steps S2 to S6 until the relation of f1≈f2 is satisfied and thus precisely detects the frequency near the resonant frequency.

The processing routine for detection in the control unit 6 is appropriately executed upon starting or driving the ultrasonic actuator 1.

The control unit 6 controls the oscillating unit 4 so that the frequency is the oscillating one near the resonant frequency which is detected by executing the above-mentioned processing routine for detection. Under the control operation of the control unit 6, the oscillating unit 4 outputs, to the driving unit 3, a predetermined frequency as the resonant frequency of the ultrasonic transducer 1A and the original signal of the frequency signal with a predetermined voltage. The driving unit 3 increases or decreases the voltage of the original signal to the best voltage for driving the ultrasonic transducer 1A, and applies the voltage to the ultrasonic transducer 1A.

Thus, the ultrasonic transducer 1A having the frequency signal applied generates ultrasonic elliptical vibrations and therefore the friction force is generated between the ultrasonic transducer 1A and the driven unit 2 in contact therewith. Hence, the ultrasonic actuator 1 is driven with the high driving-efficiency.

FIGS. 4A and 4B show characteristics of the ultrasonic actuator 1 which is driving-controlled by the driving method of the ultrasonic actuator driving apparatus as mentioned above. That is, in the characteristics of the frequency with respect to the velocity shown in FIG. 4A, the ultrasonic actuator 1 sharply reduces its velocity by the driving at the frequency f lower than the resonant frequency (shown by a dotted line in FIG. 3A). On the contrary, the ultrasonic actuator 1 gradually reduces its velocity by the driving at the frequency f higher than the resonant frequency and then sharply reduces its velocity at one point.

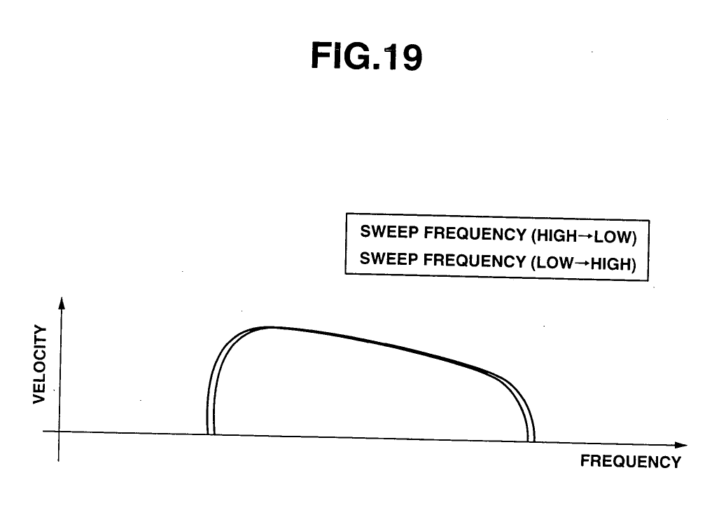

The ultrasonic actuator 1 does not change its characteristics of the frequency with respect to the velocity due to the sweeping direction of the frequency and thus the hysteresis phenomenon hardly exists. That is, referring to FIG. 19, the difference hardly exists between the characteristics of the frequency with respect to the velocity obtained by sweeping the frequency from the frequency voltage higher than the resonant frequency voltage toward the frequency voltage lower and characteristics by sweeping the frequency from the frequency voltage lower than the resonant frequency voltage toward the frequency voltage higher.

In addition to the characteristics of the frequency with respect to the velocity, referring to FIG. 4B, the phase difference between the voltage and the current and the frequency characteristics of the ultrasonic actuator 1 have a characteristic that the phase difference sharply changes near the resonant frequency and a characteristic which does not depend on the sweeping direction of the frequency. Thus, the ultrasonic actuator driving apparatus drives the ultrasonic actuator 1 with the high driving-efficiency by applying the frequency signal near the resonant frequency to the ultrasonic transducer 1A in the ultrasonic actuator 1 having the above-mentioned characteristics by using the ultrasonic actuator driving apparatus.

According to the first embodiment, even when the change in the external factors such as the temperature change results in the change in the resonant state of the ultrasonic actuator, the control unit 6 enables the ultrasonic transducer 1A to be oscillated as detected by the vibration information detecting unit 5. For example, the frequency near the resonant one of the ultrasonic transducer 1A is accurately detected based on parameters such as the phase difference between the current and the voltage. Further, the oscillating unit 4 is controlled so as to generate the frequency signal near the resonant one detected, thereby driving the ultrasonic actuator 1 with the high driving-efficiency.

According to the first embodiment, although the phase difference between the voltage and the current of the ultrasonic transducer 1A is used as the parameter indicating the oscillating state of the ultrasonic transducer 1A, which is detected by the vibration information detecting unit 5, the present invention is not limited to this. For example, as shown by a dotted line in FIG. 1, it is possible to detect the phase difference between the voltage of the frequency signal of the oscillating unit 4 and the current of the frequency signal applied to the ultrasonic transducer 1A and to output the detected phase difference to the control unit 6.

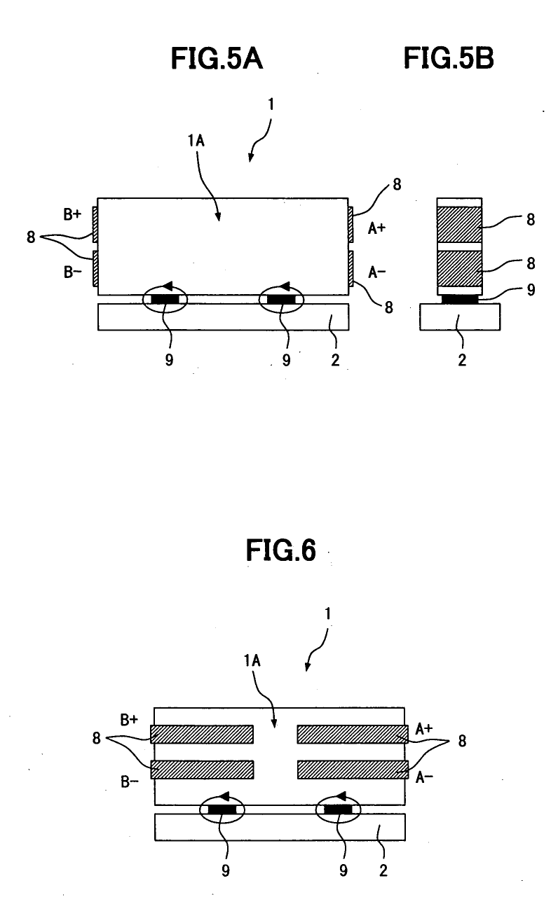

FIGS. 5A and 5B show the first structure-example of the ultrasonic actuator 1 used for the ultrasonic actuator driving apparatus according to the first embodiment. FIG. 5A is a front view and FIG. 5B is a side view. FIG. 6 is a front view showing the second structure-example of the ultrasonic actuator 1.

The ultrasonic actuator driving apparatus according to the first embodiment comprises the ultrasonic actuator 1 shown in FIG. 5A. Referring to FIGS. 5A and 5B, the ultrasonic actuator 1 comprises: the ultrasonic transducer 1A comprising a prismatic piezoelectric laminated member; the driven unit 2 which is arranged in contact with the piezoelectric laminated member of the ultrasonic transducer 1A via a friction member 9, which will be described later; external electrodes 8 arranged at two portions on the right and left side surfaces of the piezoelectric laminated member of the ultrasonic transducer 1A; and the friction members 9 adhered to two portions on the bottom of the piezoelectric laminated member of the ultrasonic transducer 1A. Predetermined pressure is applied to the ultrasonic transducer 1A by predetermined pressing means (not shown).

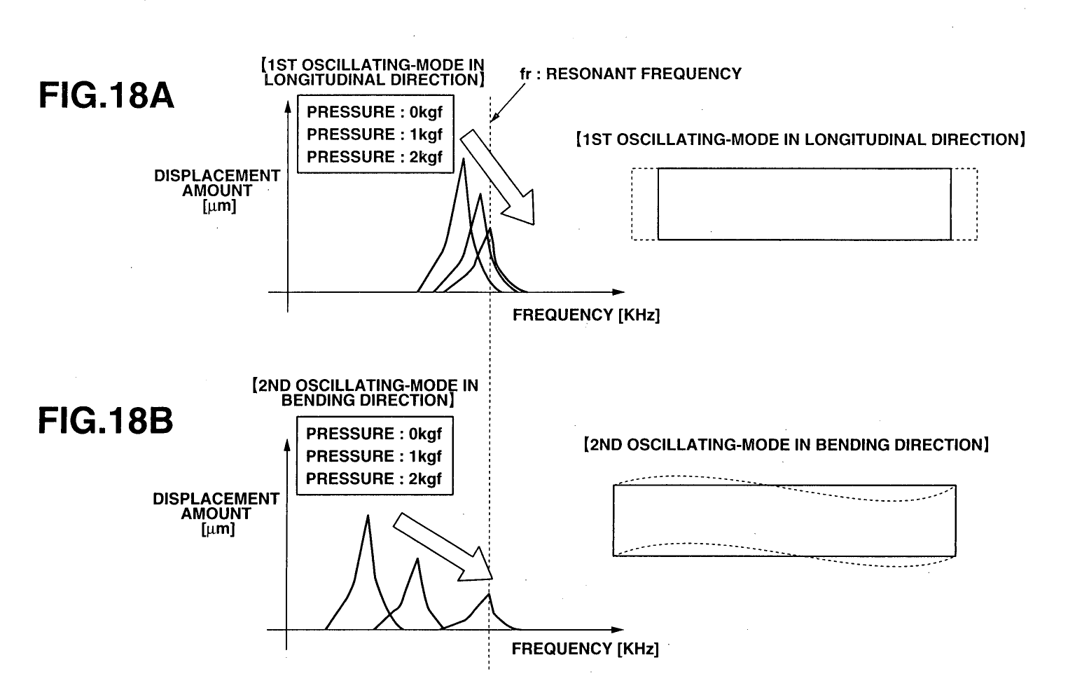

In the case of using the above-mentioned ultrasonic transducer 1A, when the level of pressure applied to the ultrasonic transducer 1A changes, the characteristics of the frequency with respect to the displacement amount of the ultrasonic transducer 1A change. That is, referring to FIGS. 18A and 18B, as the pressure increases to 0 kgf, 1 kgf, and 2 kgf, the characteristics of the frequency with respect to the displacement amount shift to the high frequency with, entirely, the lower displacement amount. Further, between the first oscillating-mode in the longitudinal direction and the second oscillating-mode in the bending direction, the characteristics of the frequency with respect to the displacement amount differ in the degree to shift to the higher frequency as mentioned above. According to the first embodiment, the horizontal to vertical ratio of the prismatic piezoelectric laminated member is set to a predetermined value, and thus the resonant frequency in the first oscillating-mode in the longitudinal direction matches the resonant frequency in the second oscillating-mode in the bending direction under the predetermined pressure.

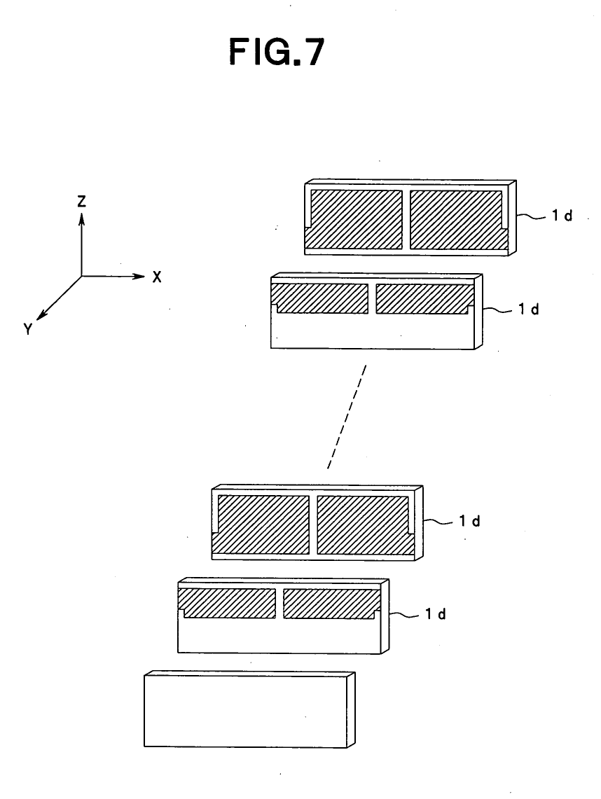

Referring to FIG. 7, the piezoelectric laminated member in the ultrasonic transducer 1A is structured by integrally laminating thin rectangular piezoelectric plates 1d subjected to the internal electrode processing in the Y axial direction (depth direction of the ultrasonic transducer 1A perpendicular to the oscillating direction of the ultrasonic transducer 1A).

The external electrodes 8 on the right in FIG. 7 are attached to internal electrode exposing portions (not shown) projected from the right surface portion in FIG. 7 of the piezoelectric laminated member in the ultrasonic transducer 1A, thus forming two electric terminals (A+ and A−) as a terminal A (phase A). The external electrodes 8 on the left in FIG. 7 are attached to internal electrode exposing portions (not shown) projected from the left surface portion in FIG. 7 of the piezoelectric laminated member in the ultrasonic transducer 1A, thus forming two electric terminals (B+ and B−) as a terminal B (phase B). In this case, the terminals A− and B− are the grounds of the A and B phases and therefore may have electrically similar potentials by using leads or the like.

In the external electrodes 8, the leads are connected by soldering (not shown) and the leads are connected to the driving unit 3 and the vibration information detecting unit 5.

The friction members 9 are arranged at the belly of the bending vibrations which are generated on the bottom of the piezoelectric laminated member in contact with the driven unit 2.

Preferably, the ultrasonic transducer 1A may have the dimension of 5 to 20 mm in the longitudinal direction according to the first embodiment. Further, preferably, the pressure may be 0.1 to 3.0 kgf when the ultrasonic actuator 1 comprises the ultrasonic transducer 1A and the driven unit 2.

According to the first embodiment, the ultrasonic actuator 1 with the above structure is used, thereby detecting the frequency near the resonant one even when the change in the external factor results in the change of the resonant state of the ultrasonic transducer 1A. The frequency signal near the detected resonant frequency is applied and, advantageously, the ultrasonic actuator 1 is driven with the high driving-efficiency. Further, with the above-structured ultrasonic transducer 1A, the number of parts is reduced and the variation in individuals is suppressed. Furthermore, a Q value of the ultrasonic transducer 1A is designed to be contact, the resonant frequency in the first oscillating-mode in the longitudinal direction matches the resonant frequency in the second oscillating-mode in the bending direction under a predetermined pressure and, advantageously, the processing routine for detecting the resonant frequency is executed.

Although the external electrodes 8 of the ultrasonic transducer 1A are arranged on both sides of the piezoelectric laminated member in the longitudinal direction as external surfaces of the piezoelectric laminated member according to the first embodiment, the present invention is not limited to this. As shown in the second structure-example in FIG. 6, the external electrodes 8 may be pulled out from the side surface and may be formed on the surface of the piezoelectric laminated member or may be arranged at the position corresponding to the back surface of the piezoelectric laminated member.

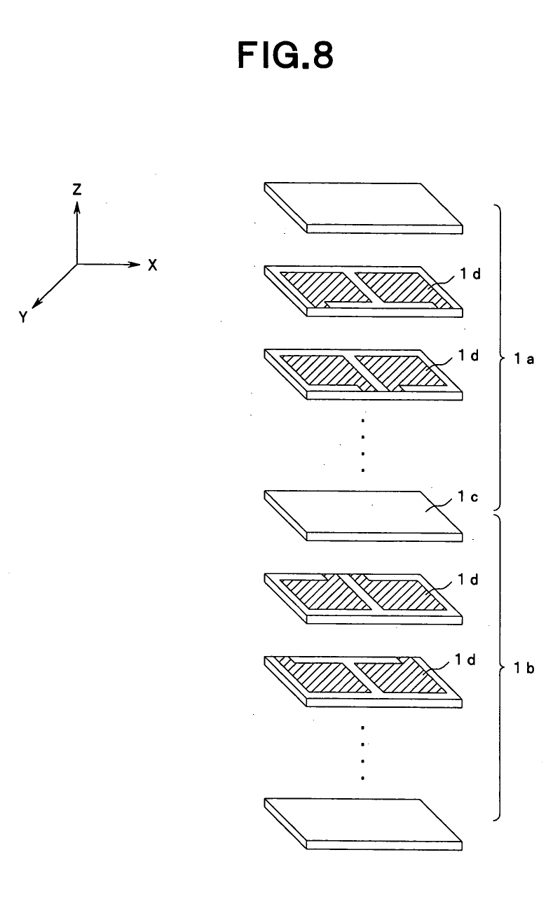

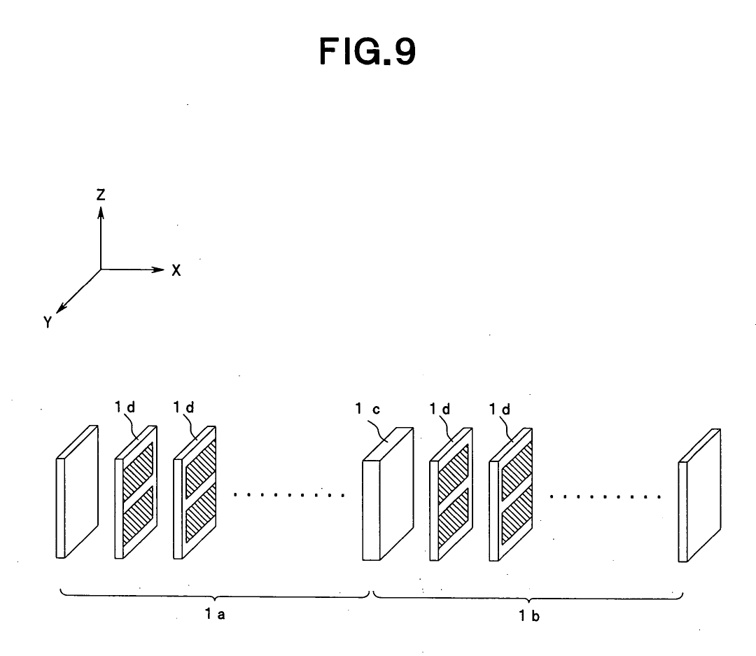

Further, although the laminating direction of the piezoelectric laminated member of the ultrasonic transducer 1A is the Y axial direction according to the first embodiment, the present invention is not limited to this. Referring to FIG. 8, a first piezoelectric laminated member 1a as the laminated member sharing approximately the upper half of ultrasonic transducer 1A and a second piezoelectric laminated member 1b as the laminated member sharing approximately the bottom half may be laminated via an insulating piezoelectric sheet lc in the Z axial direction (vertical direction of the driving direction of the ultrasonic transducer 1A). Further, referring to FIG. 9, the first piezoelectric laminated member 1a as the laminated member sharing approximately the left half of ultrasonic transducer 1A and the second piezoelectric laminated member 1b as the laminated member sharing approximately the right half may be laminated via the insulating piezoelectric sheet 1c in the X axial direction (horizontal direction similar to the driving direction of the ultrasonic transducer 1A).

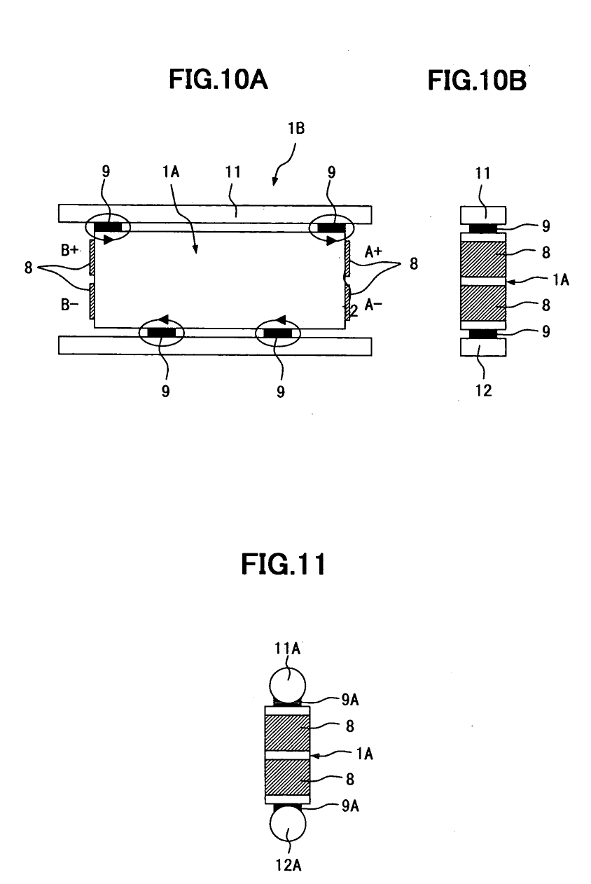

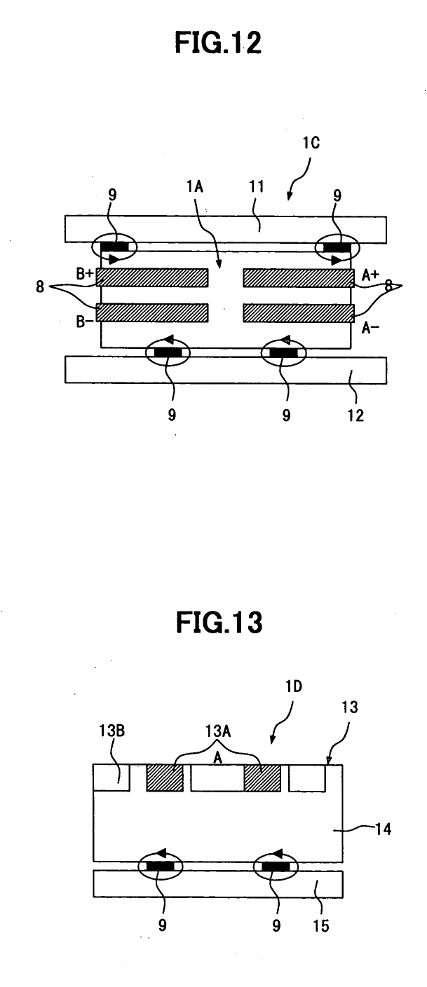

FIGS. 10A and 10B show the third structure-example of the ultrasonic actuator used for the ultrasonic actuator driving apparatus according to the first embodiment. FIG. 10A is a front view and FIG. 10B is a side view. FIG. 11 is a side view showing the fourth structure-example of the ultrasonic actuator. FIG. 12 is a front view showing the fifth structure-example of the ultrasonic actuator. FIG. 13 is a front view showing the sixth structure-example of the ultrasonic actuator. In FIGS. 10A to 13, the same components as those of the first and second structure-examples are shown by the same reference numerals, a description thereof is omitted, and only different portions will be described.

Referring to FIG. 10A, the ultrasonic actuator driving apparatus according to the first embodiment comprises an ultrasonic actuator 1B. Referring to FIGS. 10A and 10B, the ultrasonic actuator 1B comprises the friction members 9 at least at two positions on the top and bottom of the piezoelectric laminated member forming the ultrasonic transducer 1A and a first guide 11 and a second guide 12 which apply predetermined pressure to the piezoelectric laminated member and sandwich the piezoelectric laminated member. Predetermined pressure is applied to the ultrasonic transducer 1A by predetermined pressing means (not shown) including the first guide 11 and the second guide 12.

Similarly to the case of using the ultrasonic transducer 1A, the characteristics of the frequency with respect to the displacement amount of the ultrasonic transducer 1A change in accordance with the change in pressure level applied to the ultrasonic transducer 1A. That is, referring to FIGS. 18A and 18B, as the pressure increases to 0 kgf, 1 kgf, and 2 kgf, in the characteristics of the frequency with respect to the displacement amount, the displacement amount entirely decreases and the frequency is higher. Further, between the first oscillating-mode in the longitudinal direction and the second oscillating-mode in the bending direction, the characteristics of the frequency with respect to the displacement amount differ in the degree to shift to the higher frequency as mentioned above. According to the first embodiment, the horizontal to vertical ratio of the prismatic piezoelectric laminated member is set to a predetermined value, and thus the resonant frequency in the first oscillating-mode in the longitudinal direction matches that in the second oscillating-mode in the bending direction under the predetermined pressure.

Preferably, the friction members 9 may be arranged at arbitrary positions for obtaining an output characteristic at the highest level of the ultrasonic actuator 1B, namely, at the positions for ultrasonic elliptical vibration at the highest level of the ultrasonic transducer 1A. Generally, the elliptical vibration becomes the driving source and therefore the elliptical vibration is generated in at least one friction member 9 as shown by an arrow in FIG. 10A. The friction members 9 may be arranged so as to prevent, from being null, the total driving force caused by the vibration at the entire positions in the friction members 9.

According to the first embodiment, preferably, the ultrasonic transducer 1A may have the dimension of 5 to 20 mm in the longitudinal direction. Further, preferably, the applied pressure may be 30 gf to 100 gf, when the ultrasonic actuator 1B comprises the first and second guides 11 and 12.

According to the first embodiment, the laminating direction of the piezoelectric laminated member of the ultrasonic transducer 1A and the characteristics of the ultrasonic actuator 1B are the same as those in the first structure-example.

A according to the first embodiment, the ultrasonic actuator driving apparatus applies the driving signal of the frequency signal to the ultrasonic actuator 1B and then the elliptical vibration is generated near the friction members 9 in the ultrasonic transducer 1A. Therefore, the ultrasonic transducer 1A is guided by the first and second guides 11 and 12 and, simultaneously, is driven on the right and left.

Other operations are the same as those in the first structure-example.

The ultrasonic actuator 1B with the above structure is used, thereby detecting the frequency near the resonant one even when the resonant state of the ultrasonic transducer 1A changes with the change in the external factor. The detected frequency signal near the resonant frequency is applied. Advantageously, the ultrasonic actuator 1B is driven with the high driving efficiency. Further, the ultrasonic actuator driving apparatus uses the ultrasonic transducer 1A with the above structure and thus the number of parts decreases. Furthermore, the variation in individuals is suppressed. The Q value of the ultrasonic transducer 1A is designed to be constant and the resonant frequency in the first oscillating-mode in the longitudinal direction matches that in the second oscillating-mode in the bending direction under a predetermined pressure and, advantageously, the processing routine for detecting the resonant frequency is executed.

With the structure examples, although the external electrodes 8 of the ultrasonic transducer 1A are arranged on both sides of the piezoelectric laminated member in the longitudinal direction as external surfaces of the piezoelectric laminated member, the present invention is not limited to this. As shown in the fifth structure-example in FIG. 12, the external electrodes 8 may be pulled out from the side surface and may be formed on the surface of the piezoelectric laminated member or may be arranged at the position corresponding to the back surface of the piezoelectric laminated member.

Further, referring to FIG. 10A, although the first and second guides 11 and 12 are prismatic, the present invention is not limited to this. For example, as shown in the fourth structure-example in FIG. 11, the first and second guides 11 and 12 may be cylindrical or semi-cylindrical. In accordance therewith, the-friction members 9 need to be U-shaped or V-shaped matching the shapes of the first and second guides 11 and 12.

Although the ultrasonic actuators 1, 1B, and 1C in the first to fifth structure-examples are structured by integrating the piezoelectric laminated members via the insulating layer (not shown), the present invention is not limited to this. As shown in the sixth structure-example in FIG. 13, an ultrasonic actuator 1D may comprise an ultrasonic transducer comprising: at least two laminating piezoelectric elements 13A which are fixed in parallel in the longitudinal direction of a prismatic basic elastic member 14; holding elastic members 13B which press and sandwich the two or more laminating piezoelectric elements 13A to the basic elastic member 14; the friction members 9 arranged at the belly positions of the bending vibration generated on the surface of the basic elastic member 14 in contact with a contact portion 15 as a driven portion.

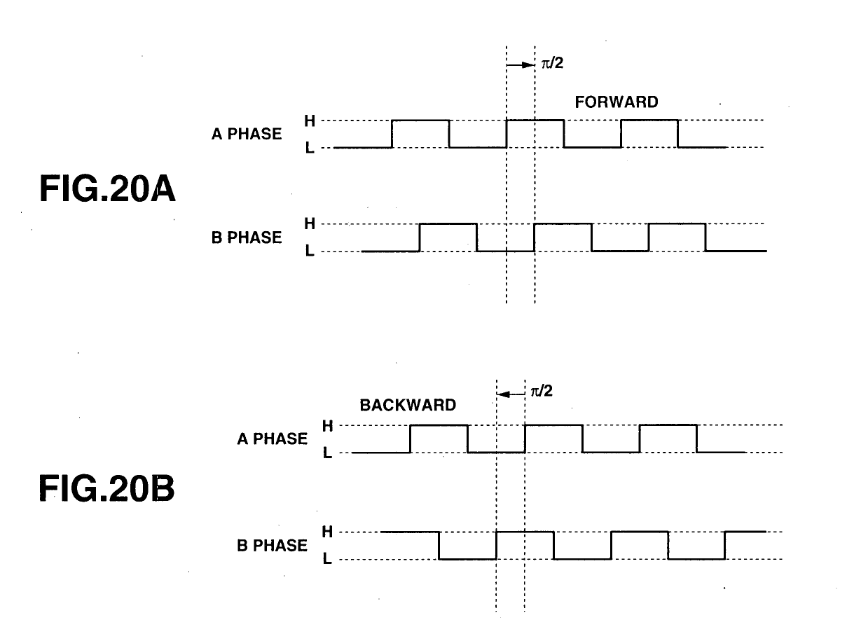

According to the first embodiment, for the purpose of driving the ultrasonic actuator 1, frequency signals with waveforms shown in FIGS. 20A and 20B are applied from the driving unit 3 to external electrodes with two phases of the A phase (A+, A−) and the B phase (+B, −B) of the ultrasonic transducer 1A in the ultrasonic actuator 1.

FIG. 20A shows the waveforms of the frequency signal for driving forward the ultrasonic actuator 1. A signal obtained by delaying the phase of the signal applied to the B phase at an angle of 90° (π/2) is applied to the signal applied to the A phase of the ultrasonic transducer 1A. The applied signal enables the excitation and overlapping of the first oscillating-mode in the longitudinal direction and the second oscillating-mode in the bending direction to the friction members 9 arranged between the driven unit 2 and the ultrasonic transducer 1A of the ultrasonic actuator 1. Thus, the elliptical vibration is generated around a predetermined direction and the driven unit 2 is driven forward.

FIG. 20B shows the waveform of the frequency signal for driving backward the ultrasonic actuator 1. A signal obtained by advancing the phase of the signal applied to the B phase at an angle of 90° (π/2) is applied to the signal applied to the A phase of the ultrasonic transducer 1A. Similarly to the case of the signal for driving forward the ultrasonic actuator 1, the applied signal enables the excitation and overlapping of the first oscillating-mode in the longitudinal direction and the second oscillating-mode in the bending direction to the friction members 9 arranged between the driven unit 2 and the ultrasonic transducer 1A of the ultrasonic actuator 1. Thus, the elliptical vibration is generated around a direction opposite to the predetermined direction in the forward case and the driven unit 2 is driven backward.

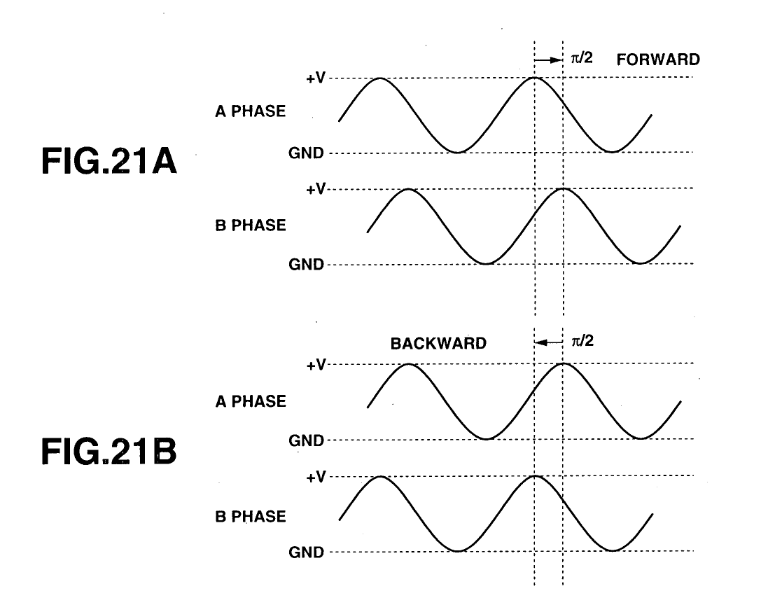

Similarly, the frequency signals with sine waves shown in FIGS. 21A and 21B are applied to the ultrasonic actuator 1 and the ultrasonic actuator 1 is driven forward as shown in FIG. 21A and is driven backward as shown in FIG. 21B.

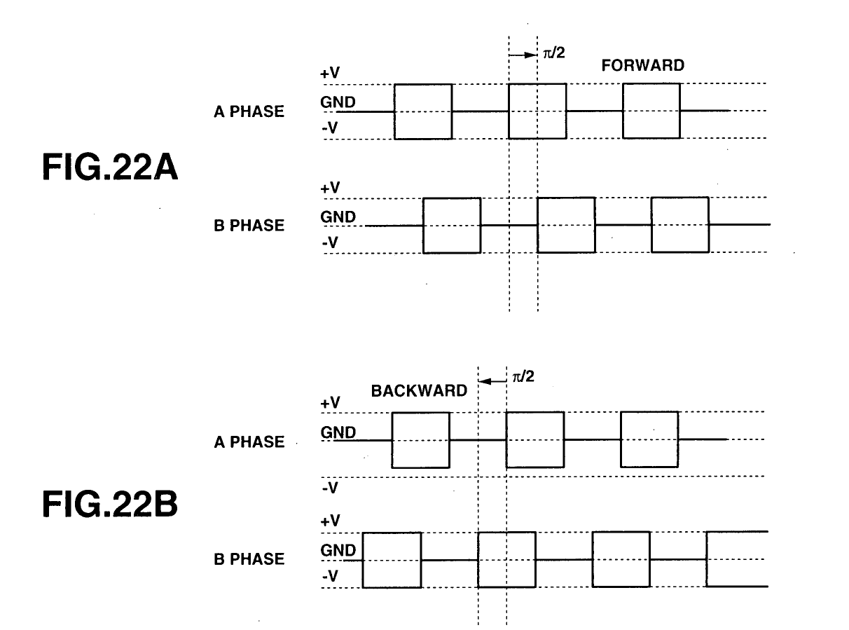

Referring to FIGS. 22A and 22B, similarly, the frequency signals of +V and −V are applied to A+, B+ and to A−, B− respectively from the driving unit 3 to the external electrode 8 with the two phases of the A phase (A+, A−) and the B phase (B+, B−) of the ultrasonic transducer 1A in the ultrasonic actuator 1 by using the pairs of (A+/A−) and (B+/B−), respectively, based on the GND. Then, the ultrasonic actuator 1 is driven forward as shown in FIG. 22A and is driven backward as shown in FIG. 22B.

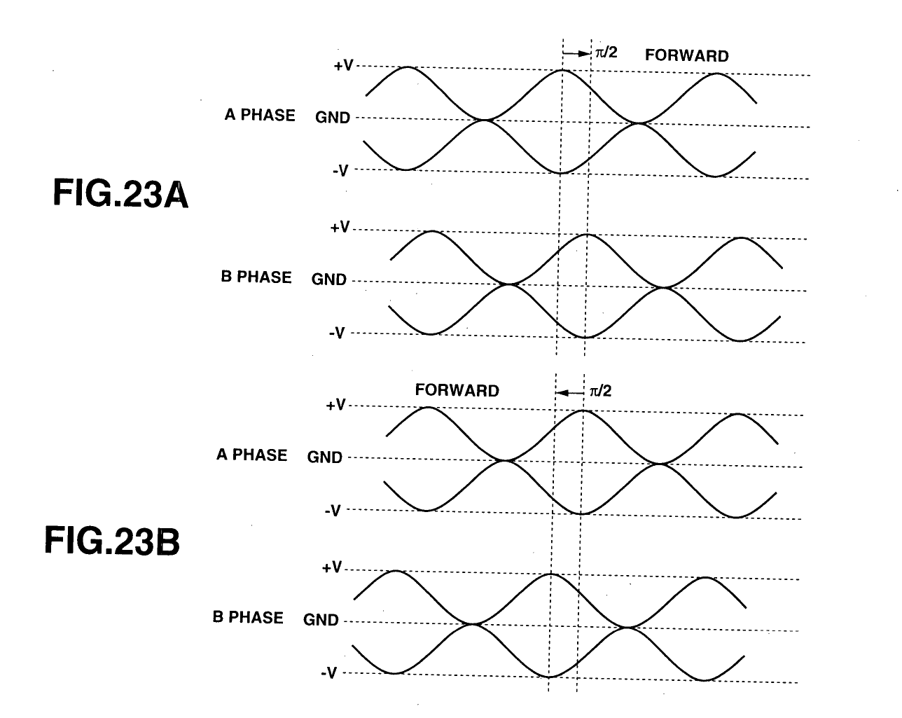

The applied frequency signals with the sine waves shown in FIGS. 23A and 23B drive forward the ultrasonic actuator 1 as shown in FIG. 23A and drive it backward as shown I FIG. 23B.

The waveforms of the frequency signals applied to the ultrasonic transducer 1A are not limited to the above-mentioned rectangular waves and the sine waves but may be zigzag.

### Second embodiment

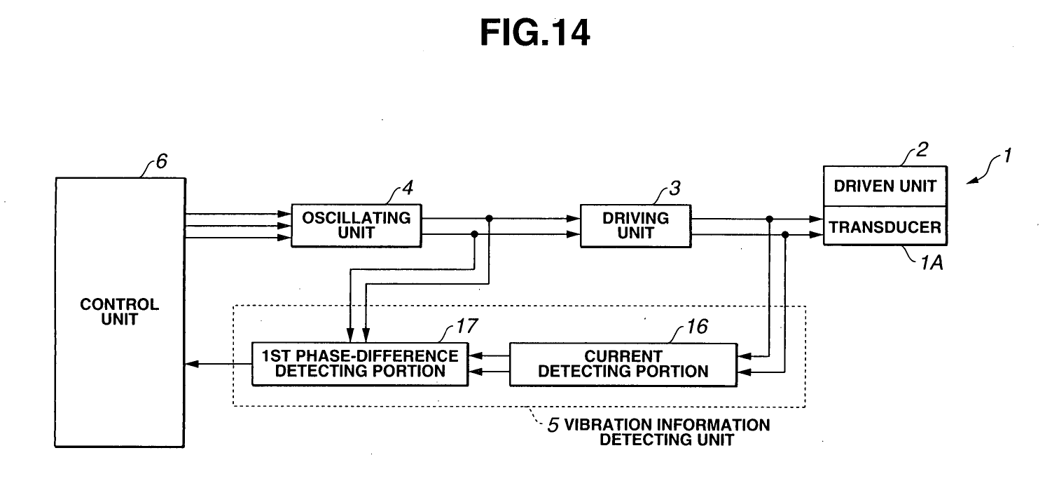

FIG. 14 is a block diagram showing the entire structure of an ultrasonic actuator driving apparatus according to the second embodiment of the present invention. Referring to FIG. 14, the same components as those according to the first embodiment are shown by the same reference numerals, a description thereof is omitted, and only different portions will be described.

The ultrasonic actuator driving apparatus according to the second embodiment comprises a current detecting portion 16 and a first phase-difference detecting portion 17 in the vibration information detecting unit 5. The current detecting portion 16 is connected to the output terminal of the driving unit 3, detects the current of the frequency signal applied to the ultrasonic transducer 1A, and outputs the detecting result to the first phase-difference detecting portion 17. The first phase-difference detecting portion 17 is connected to the output terminal of the oscillating unit 4 and the control unit 6, detects the phase difference between the voltage of the frequency signal from the oscillating unit 4 and the current detected by the current detecting portion 16, and outputs the detected phase difference to the control unit 6.

Similarly to the first embodiment, the control unit 6 detects the frequency near the resonant one of the ultrasonic transducer 1A changed in the oscillating state by the external environment, based on the phase difference between the voltage of the frequency signal from the oscillating unit 4 and the current detected by the current detecting portion 16, which is detected by the vibration information detecting unit 5. The control unit 6 controls the oscillating unit 4 so that it has the frequency signal of the detected resonant frequency. Other structures are the same as those according to the first embodiment.

The ultrasonic actuator driving apparatus according to the second embodiment operates, similarly to the first embodiment. That is, when the change in external factors such as the temperature change results in the change in the resonant state of the ultrasonic actuator, the control unit 6 precisely detects the frequency near the resonant one of the ultrasonic transducer 1A based on the phase difference between the voltage of the frequency signal from the oscillating unit 4 and the current detected by the current detecting portion 16, which is detected by the vibration information detecting unit 5. Further, the control unit 6 controls the oscillating unit 4 so that it generates the frequency signal near the detected resonant frequency, thereby driving the ultrasonic actuator 1 with the high driving-efficiency.

According to the second embodiment, the same advantages as those according to the first embodiment are obtained. Further, the voltage is controlled at the TTL (Transistor-Transistor Logic) level as one of general digital IC circuits and therefore the costs are reduced without adding any components such as another comparator.

According to the second embodiment, the waveform of the frequency signal applied to the ultrasonic transducer 1A may be rectangular, sine, or zigzag, similarly to the first embodiment.

According to the second embodiment, although the control unit 6 detects and outputs the phase difference between the voltage of the frequency signal of the oscillating unit 4 and the current of the frequency signal applied to the ultrasonic transducer 1A, the present invention is not limited to this. The control unit 6 may detect and output the phase difference between the voltage and the current of the frequency signal applied to the ultrasonic transducer 1A.

### Third embodiment

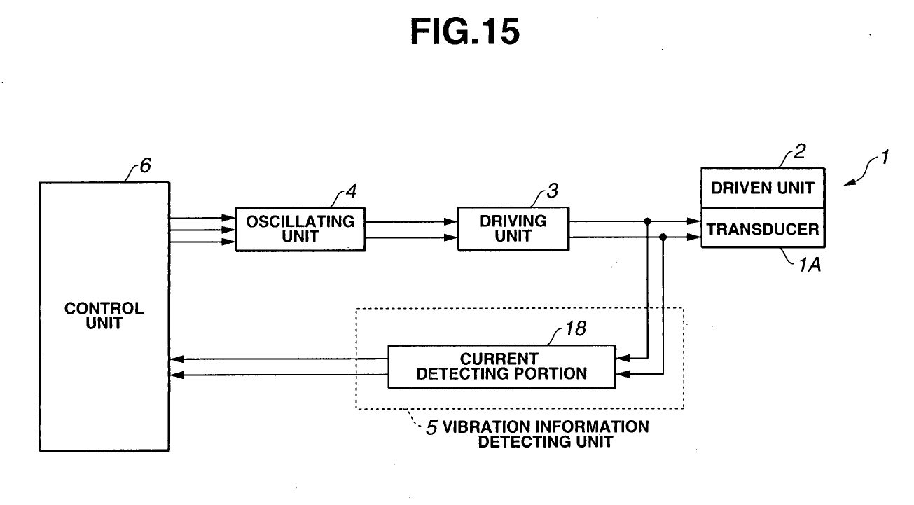

FIG. 15 is a block diagram showing the entire structure of an ultrasonic actuator driving apparatus according to the third embodiment of the present invention. Referring to FIG. 15, the same components as those according to the first embodiment are shown by the same reference numerals, a description is omitted, and only different portions are described.

The ultrasonic actuator driving apparatus according to the third embodiment comprises a current detecting portion 18 in the vibration information detecting unit 5 according to the first embodiment. The current detecting portion 18 is connected to the output terminal of the driving unit 3, detects the current level of the frequency signal applied to the ultrasonic transducer 1A, and outputs the detecting result to the control unit 6.

The control unit 6 performs the detecting processing based on the current level of the frequency signal applied to the ultrasonic transducer 1A, which is detected by the vibration information detecting unit 5, so as to detect the frequency near the resonant one of the ultrasonic transducer 1A changed in the oscillating state due to the external environment. Further, the control unit 6 controls the oscillating unit 4 so as to have the frequency signal near the detected resonant frequency. Other structures are the same as those according to the first embodiment.

The ultrasonic actuator driving apparatus according to the third embodiment operates, similarly to the first embodiment. That is, in the ultrasonic actuator driving apparatus according to the third embodiment precisely, the control unit 6 detects the frequency near the detected resonant frequency of the ultrasonic transducer 1A based on the current level of the frequency signal applied to the ultrasonic transducer 1A, which is detected by the vibration information detecting unit 5 even when the change in external factors such as the temperature change results in the change in the resonant state of the ultrasonic actuator. Further, the control unit 6 controls the oscillating unit 4 so as to generate the frequency signal near the detected resonant frequency and thus the ultrasonic actuator 1 is driven with the high driving-efficiency.

Therefore, according to the third embodiment, the same advantages as those according to the first embodiment are obtained. In addition, since the number of parts is reduced, the costs decrease, as compared with the second embodiment.

Further, according to the third embodiment, the waveform of the frequency signal applied to the ultrasonic transducer 1A may be rectangular, sine, or zigzag, similarly to the above-mentioned embodiments.

### Fourth embodiment

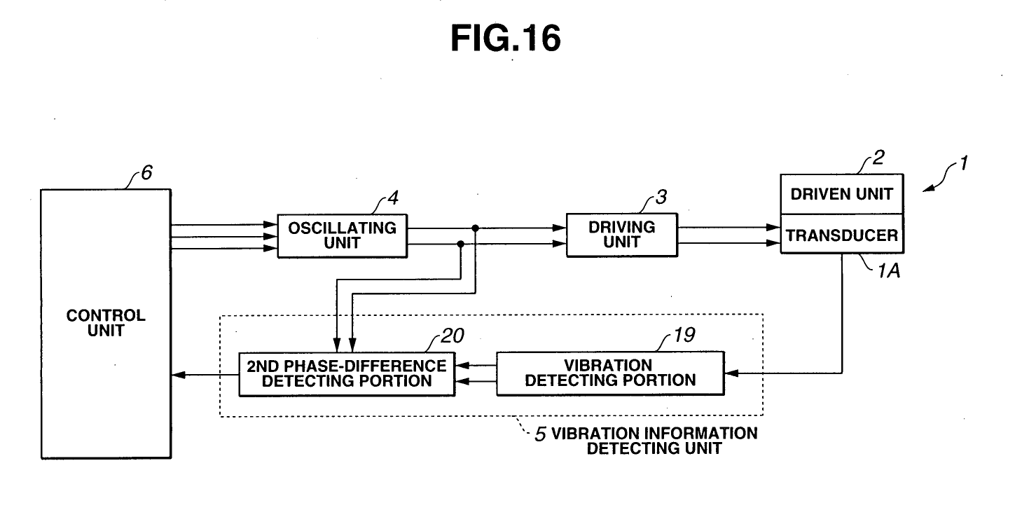

FIG. 16 is a block diagram showing the entire structure of an ultrasonic actuator driving apparatus according to the fourth embodiment of the present invention. Referring to FIG. 16, the same components as those according to the first embodiment are shown by the same reference numerals, a description is omitted, and only different portions are described.

The ultrasonic actuator driving apparatus according to the fourth embodiment comprises a vibration detecting portion 19 and a second phase-difference detecting portion 20 in the vibration information detecting unit 5 according to the first embodiment. The vibration detecting portion 19 is connected to the ultrasonic transducer 1A, detects a vibrating waveform of the ultrasonic transducer 1A, and outputs the detecting result to the second phase-difference detecting portion 20. The second phase-difference detecting portion 20 is connected to the output terminal of the oscillating unit 4 and the control unit 6, detects the phase difference between the voltage of the frequency signal from the oscillating unit 4 and the vibrating waveform detected by the vibration detecting portion 19, and outputs the detected phase difference to the control unit 6.

Similarly to the first embodiment, the control unit 6 performs the detecting processing based on the phase difference between the voltage of the frequency signal from the oscillating unit 4 and the vibrating waveform detected by the vibration detecting portion 19, which is detected by the vibration information detecting unit 5, so as to detect the frequency near the resonant one of the ultrasonic transducer 1A changed in the oscillating state due to the external environment. The control unit 6 controls the oscillating unit 4 so as to have the frequency near the detected resonant frequency. Other structures are the same as those according to the first embodiment.

The ultrasonic actuator driving apparatus according to the fourth embodiment operates, similarly to the first embodiment. That is, even when the change in external factors such as the temperature change results in the change in resonant state of the ultrasonic actuator, the control unit 6 precisely detects the frequency near the resonant one of the ultrasonic transducer 1A based on the phase difference between the voltage of the frequency signal from the oscillating unit 4 and the vibrating waveform detected by the vibration detecting portion 19, which is detected by the vibration information detecting unit 5. Further, the control unit 6 controls the oscillating unit 4 so that it generates the frequency signal near the detected resonant frequency, thereby driving the ultrasonic actuator 1 with the high driving-efficiency.

According to the fourth embodiment, the same advantages as those according to the first embodiment are obtained. Further, since the oscillating state of the ultrasonic transducer 1A is directly detected, the frequency near the resonant one of the ultrasonic actuator 1 is precisely detected. In addition, the voltage is controlled at the TTL (Transistor-Transistor Logic) level as one of general digital IC circuits and therefore the costs are reduced without adding any components such as another comparator.

According to the fourth embodiment, the waveform of the frequency signal applied to the ultrasonic transducer 1A may be rectangular, sine, or zigzag.

Further, although the signal inputted to the second phase-difference detecting portion 20 is the voltage of the frequency signal of the oscillating unit 4 according to the fourth embodiment, the present invention is not limited to this. The voltage of the frequency signal applied to the ultrasonic transducer 1A may be inputted to the second phase-difference detecting portion 20. Further, the signal inputted to the second phase-difference detecting portion 20 is the vibrating waveform from the vibration detecting portion 19 and the signal may be the current or voltage of the vibrating waveform, or the phase difference between the current and the voltage.

### Fifth embodiment

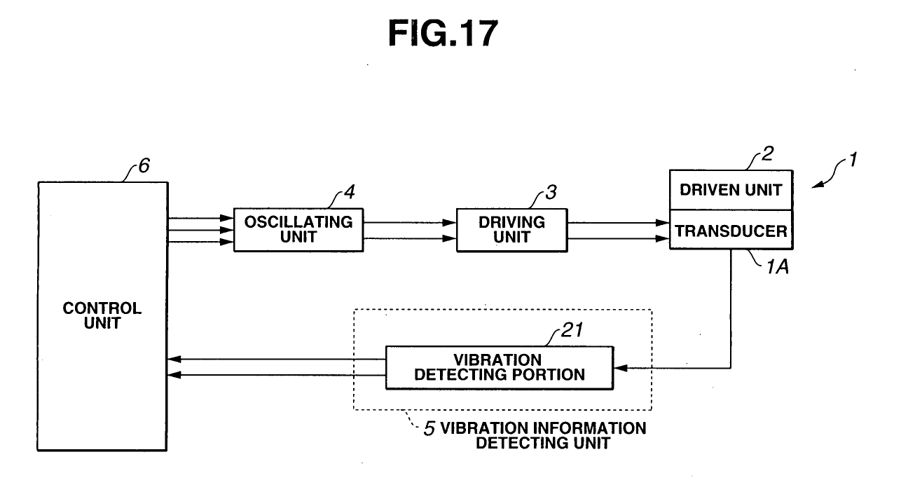

FIG. 17 is a block diagram showing the entire structure of an ultrasonic actuator driving apparatus according to the fifth embodiment of the present invention. Referring to FIG. 17, the same components as those according to the first embodiment are shown by the same reference numerals, a description is omitted, and only different portions are described.

The ultrasonic actuator driving apparatus according to the fifth embodiment comprises a vibration detecting portion 21 in the vibration information detecting unit 5 according to the first embodiment. The vibration detecting portion 21 is connected to the ultrasonic transducer 1A. The vibration detecting portion 21 detects the vibrating waveform of the ultrasonic transducer 1A functioning as a parameter indicating the oscillating state of the ultrasonic transducer 1A and outputs the detecting result to the control unit 6.

The control unit 6 performs the detecting processing based on the vibrating waveform of the ultrasonic transducer 1A, which is detected by the vibration information detecting unit 5, so as to detect the frequency near the resonant one of the ultrasonic transducer 1A changed in the oscillating state due to the external environment. Further, the control unit 6 controls the oscillating unit 4 so as to have the frequency signal near the detected resonant frequency. Other structures are the same as those according to the first embodiment.

The ultrasonic actuator driving apparatus according to the fifth embodiment operates, similarly to the first embodiment. That is, in the ultrasonic actuator driving apparatus according to the fifth embodiment, the control unit 6 precisely detects the frequency near the detected resonant frequency of the ultrasonic transducer 1A based on the vibrating waveform of the ultrasonic transducer 1A, which is detected by the vibration information detecting unit 5 even when the change in external factors such as the temperature change results in the change in resonant state of the ultrasonic actuator. Further, the control unit 6 controls the oscillating unit 4 so as to generate the frequency signal near the detected resonant frequency and thus the ultrasonic actuator 1 is driven with the high driving-efficiency.

Therefore, according to the fifth embodiment, the same advantages as those according to the first embodiment are obtained. In addition, since the number of parts is reduced, the costs decrease, as compared with the fourth embodiment.

Further, according to the fifth embodiment, the waveform of the frequency signal applied to the ultrasonic transducer 1A may be rectangular, sine, or zigzag, similarly to the above-mentioned embodiments.

According to the fifth embodiment, the signal outputted to the control unit 6 is the vibrating waveform from the vibration detecting portion 21 and further the signal may be the current and the voltage of the vibrating waveform or the phase difference between the current and voltage.

According to the first to fifth embodiments of the present invention, although the control unit 6 detects the frequency near the resonant frequency by using the phase difference between the current of the frequency applied to the ultrasonic transducer 1A and the voltage of the frequency signal from the oscillating unit 4, the present invention is not limited to this. The detecting processing may be performed by the current and the voltage of the vibrating waveform indicating the oscillating state of the ultrasonic transducer 1A, the phase difference between the current and the voltage, or the phase difference between the vibrating waveform and the voltage of the frequency signal from the oscillating unit 4.

The ultrasonic actuator according to the second to the fifth embodiments of the present invention can be any of the ultrasonic actuators in the first to sixth structure-examples according to the first embodiment.

Further, according to the method for detecting the frequency near the resonant one of the ultrasonic actuator 1, although the area for detecting the frequency including the resonant frequency of the ultrasonic actuator 1 is stepwise narrow, the present invention is not limited to this. For example, a method for detecting the frequency near the resonant one of the ultrasonic actuator 1 by continuously changing the frequency can be used.

The present invention is not limited to the first to fifth embodiments, and can variously be modified without departing from the essentials of the present invention.

In this invention, it is apparent that various modifications different in a wide range can be made on this basis of this invention without departing from the spirit and scope of the invention. This invention is not restricted by any specific embodiment except being limited by the appended claims.

1. An ultrasonic actuator driving apparatus which drives an ultrasonic transducer formed by alternately laminating a piezoelectric plate and an internal electrode, by applying a frequency signal to the ultrasonic transducer, the ultrasonic actuator driving apparatus comprising:
an oscillating unit which generates the frequency signal for driving the ultrasonic transducer;
a driving unit which amplifies the frequency signal and applies the signal to the ultrasonic transducer based on an output from the oscillating unit;
a vibration information detecting unit which detects vibration information of the ultrasonic transducer; and
a control unit which detects a frequency near a resonant one of the ultrasonic transducer based on the vibration information, sets the detected frequency as a driving frequency of the ultrasonic transducer, and controls the oscillating unit so as to generate the frequency signal based on the driving frequency.

2. An ultrasonic actuator driving apparatus according to claim 1, wherein the control unit detects the frequency near the resonant one by changing the frequency so as to stepwise narrow an area for detecting the frequency including the resonant frequency of the ultrasonic transducer.

3. An ultrasonic actuator driving apparatus according to claim 2, wherein the frequency near the resonant one is a frequency having an approximately maximum change in the vibration information.

4. An ultrasonic actuator driving apparatus according to claim 1, wherein the vibration information detecting unit is a first phase-different detecting unit which detects the phase difference between current of the frequency signal applied to the ultrasonic transducer and a voltage of the frequency signal from the oscillating unit.

5. An ultrasonic actuator driving apparatus according to claim 1, wherein the vibration information detecting unit is a current detecting unit which detects current of the frequency signal applied to the ultrasonic transducer.

6. An ultrasonic actuator driving apparatus according to claim 1, wherein the vibration information detecting unit is a second phase-difference detecting unit which detects the phase difference between a voltage of the frequency signal applied to the ultrasonic transducer and a vibrating waveform of the ultrasonic transducer.

7. An ultrasonic actuator driving apparatus according to claim 1, wherein the vibration information detecting unit is a vibration detecting unit which detects vibrations of the ultrasonic transducer.

8. An ultrasonic actuator driving apparatus according to claim 1, wherein the ultrasonic transducer comprises:
a piezoelectric laminated member which is formed by laminating piezoelectric plates in the same direction;
a friction member which is arranged to the side surface of the piezoelectric laminated member in contact with a driven unit with predetermined pressure;
an internal electrode having first electrodes and second electrodes, arranged in the piezoelectric laminated member; and
first external electrodes and second external electrodes which are conductive to the internal electrode,
wherein the driving unit applies the frequency signal to the first external electrodes and/or the second external electrodes and simultaneously generates both a first oscillating-mode and a second oscillating-mode, thereby generating ultrasonic elliptical vibrations to the ultrasonic transducer.

9. An ultrasonic actuator driving apparatus according to claim 1, wherein the ultrasonic transducer is sandwiched by first and second guide members which apply predetermined pressure to the piezoelectric laminated member via the friction member.

10. An ultrasonic actuator driving apparatus according to claim 8, wherein the piezoelectric laminated member has a predetermined external dimension and thus the resonant frequency in the first oscillating-mode matches the resonant frequency in the second oscillating-mode under the predetermined pressure.

11. An ultrasonic actuator driving method which drives an ultrasonic transducer formed by alternately laminating a piezoelectric plate and an internal electrode, by applying a frequency signal to the ultrasonic transducer, the ultrasonic actuator driving method comprising the steps of:
detecting a frequency near a resonant one of the ultrasonic transducer based on vibration information of the ultrasonic transducer;
setting the detected frequency as a driving frequency of the ultrasonic transducer; and
driving the ultrasonic transducer by applying the frequency signal to the ultrasonic transducer based on the driving frequency.

12. An ultrasonic actuator driving method according to claim 11, wherein the frequency near the resonant one is detected by changing the frequency so as to stepwise narrow an area for detecting the frequency including the resonant frequency of the ultrasonic transducer.

13. An ultrasonic actuator driving method according to claim 12, wherein the frequency near the resonant one is a frequency having an approximately maximum change in the vibration information.

14. An ultrasonic actuator driving method according to claim 11, wherein the vibration information is a phase difference between current applied to the ultrasonic transducer and a voltage of the frequency signal.

15. An ultrasonic actuator driving method according to claim 11, wherein the vibration information is current applied to the ultrasonic transducer.

16. An ultrasonic actuator driving method according to claim 11, wherein the vibration information is a phase difference between a voltage applied to the ultrasonic transducer and a vibrating waveform.

17. An ultrasonic actuator driving method according to claim 11, wherein the vibration information is a phase difference of the vibrating waveforms of the ultrasonic transducer.

18. An ultrasonic actuator driving method according to claim 11, wherein the ultrasonic transducer comprises:
a piezoelectric laminated member which is formed by laminating piezoelectric plates in the same direction;
a friction member which is arranged to the side surface of the piezoelectric laminated member in contact with a driven unit with predetermined pressure;
an internal electrode having first electrodes and second electrodes, arranged in the piezoelectric laminated member; and
first external electrodes and second external electrodes which are conductive to the internal electrode,
wherein the driving unit applies the frequency signal to the first external electrodes and/or the second external electrodes and simultaneously generates both a first oscillating-mode and a second oscillating-mode, thereby generating ultrasonic elliptical vibrations to the ultrasonic transducer.

19. An ultrasonic actuator driving method according to claim 11, wherein the ultrasonic transducer is sandwiched by first and second guide members which apply predetermined pressure to the piezoelectric laminated member via the friction member.

20. An ultrasonic actuator driving method according to claim 18, wherein the piezoelectric laminated member has a predetermined external dimension and thus the resonant frequency in the first oscillating-mode matches the resonant frequency in the second oscillating-mode under the predetermined pressure.
